(19) United States
(12) Patent Application Publication
(10) Pub. No.: US 2024/0074172 A1
(43) Pub. Date: Feb. 29, 2024

(54) SEMICONDUCTOR STORAGE DEVICE AND METHOD OF MANUFACTURING THE SAME

(71) Applicant: Kioxia Corporation, Tokyo (JP)

(72) Inventors: Keiichi SAWA, Yokkaichi Mie (JP); Tomoyuki TAKEMOTO, Nagoya Aichi (JP); Yuta KAMIYA, Nagoya Aichi (JP); Hiroyuki YAMASHITA, Yokkaichi Mie (JP); Yuta SAITO, Yokkaichi Mie (JP); Tatsunori ISOGAI, Yokkaichi Mie (JP)

(73) Assignee: Kioxia Corporation, Tokyo (JP)

(21) Appl. No.: 18/181,821

(22) Filed: Mar. 10, 2023

(30) Foreign Application Priority Data
Aug. 30, 2022 (JP) 2022-137203

(51) Int. Cl. H10B 41/27; H10B 43/27

(52) U.S. Cl. CPC H10B 41/27; H10B 43/27

(57) ABSTRACT

In one embodiment, a semiconductor storage device includes a lower electrode layer, a lower insulator, an upper electrode layer and an upper insulator along a first direction. The device further includes a first insulator provided on a side of a second direction of the upper electrode layer, and a second insulator provided between the upper electrode layer and the lower/upper/first insulator. The device further includes a charge storage layer, a third insulator and a semiconductor layer sequentially provided on a side of the second direction of the first insulator. A side face of the first insulator on a side of the upper electrode layer has a convex shape, the charge storage layer includes a first portion having a first thickness, and a second portion having a second thickness less than the first thickness, and the first portion is in contact with the first insulator.

### CROSS-REFERENCE TO RELATED APPLICATIONS

This application is based upon and claims the benefit of priority from the prior Japanese Patent Application No. 2022-137203, filed on Aug. 30, 2022, the entire contents of which are incorporated herein by reference.

### FIELD

Embodiments described herein relate to a semiconductor storage device and a method of manufacturing the same.

### BACKGROUND

In a three-dimensional semiconductor memory, the performance of a charge storage layer may be degraded when the volume of the charge storage layer is reduced. For example, if the cross-sectional shape of a side face of the charge storage layer is not flat but convex, the volume of the charge storage layer will become smaller.

### BRIEF DESCRIPTION OF THE DRAWINGS

FIG. 1 is a cross-sectional diagram illustrating the structure of a semiconductor storage device of a first embodiment;

FIGS. 2A to 6B are cross-sectional diagrams illustrating a method of manufacturing the semiconductor storage device of the first embodiment;

FIGS. 7A to 7C are cross-sectional diagrams illustrating details of the method of manufacturing the semiconductor storage device of the first embodiment;

FIG. 8 is a cross-sectional diagram illustrating the structure of a semiconductor storage device of a modified embodiment of the first embodiment;

FIG. 9 is a cross-sectional diagram illustrating the structure of a semiconductor storage device of a second embodiment;

FIG. 10 is a cross-sectional diagram illustrating the structure of a semiconductor storage device of a first modified embodiment of the second embodiment;

FIGS. 11A to 11C are cross-sectional diagrams for explaining advantages of the semiconductor storage device of the second embodiment;

FIGS. 12A to 15B are cross-sectional diagrams illustrating a method of manufacturing the semiconductor storage device of the second embodiment; and

FIG. 16 is a cross-sectional diagram illustrating the structure of a semiconductor storage device of a second modified embodiment of the second embodiment.

### DETAILED DESCRIPTION

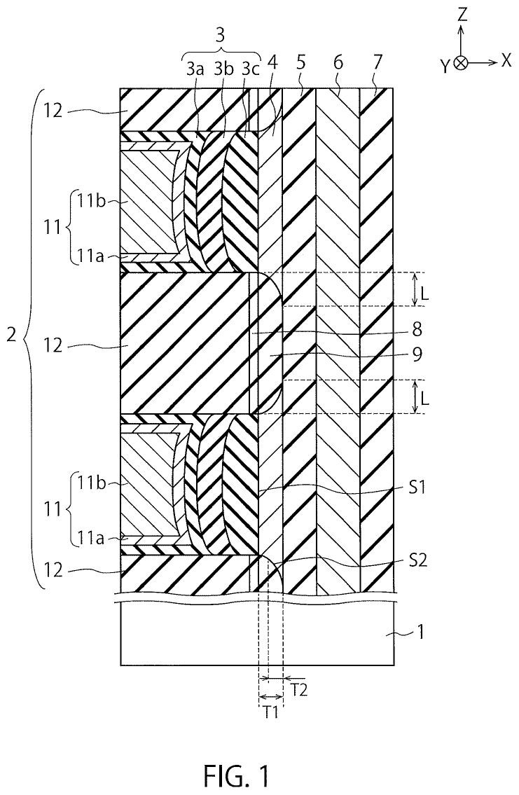

Embodiments will now be explained with reference to the accompanying drawings. In FIGS. 1 to 16, the same configurations are denoted by the same reference numerals and the same explanations will not be repeated.

In one embodiment, a semiconductor storage device includes a lower electrode layer, a lower insulator provided on a side of a first direction of the lower electrode layer, an upper electrode layer provided on a side of the first direction of the lower insulator, and an upper insulator provided on a side of the first direction of the upper electrode layer. The device further includes a first insulator provided on a side of a second direction of the upper electrode layer, the second direction intersecting with the first direction, a second insulator provided between the lower insulator and the upper electrode layer, between the upper electrode layer and the upper insulator, and between the upper electrode layer and the first insulator, a charge storage layer provided on a side of the second direction of the first insulator, a third insulator provided on a side of the second direction of the charge storage layer, and a semiconductor layer provided on a side of the second direction of the third insulator. A side face of the first insulator on a side of the upper electrode layer has a convex shape protruding toward the upper electrode layer, the charge storage layer includes a first portion having a first thickness in the second direction, and a second portion having a second thickness in the second direction, the second thickness being less than the first thickness, and the first portion is in contact with the first insulator.

### First Embodiment

FIG. 1 is a cross-sectional diagram illustrating the structure of the semiconductor storage device of a first embodiment. For example, the semiconductor storage device of the present embodiment includes a three-dimensional semiconductor storage device.

The semiconductor storage device of the present embodiment includes a substrate 1, a stacked film 2, a plurality of block insulators 3, a plurality of charge storage layers 4, a tunnel insulator 5, a channel semiconductor layer 6, a core insulator 7, a plurality of insulators 8, and a plurality of insulators 9. The stacked film 2 includes a plurality of electrode layers 11 and a plurality of insulators 12. Each electrode layer 11 includes a barrier metal layer 11a and an electrode material layer 11b. Each block insulator 3 includes an insulator 3a, an insulator 3b, and an insulator 3c. The “insulators 3b and 3c”, “insulator 3a”, “tunnel insulator 5”, “insulators 8 and 9”, and “insulator 3c” are examples of first to fifth insulators, respectively. The electrode layers 11 are examples of a lower electrode layer and an upper electrode layer, and the insulators 12 are examples of a lower insulator and an upper insulator.

The substrate 1 is, for example, a semiconductor substrate such as a silicon (Si) substrate. FIG. 1 illustrates X and Y directions that are parallel to the surface of the substrate 1 and are perpendicular to each other, and Z direction that is perpendicular to the surface of the substrate 1. The X, Y, and Z directions intersect with each other. In the present specification, +Z direction is regarded as an upward direction, and −Z direction is regarded as a downward direction. The −Z direction may match the direction of gravity, or may not match the direction of gravity. The Z direction is an example of a first direction. The X direction is an example of a second direction.

The stacked film 2 is formed on the substrate 1 and includes the plurality of electrode layers 11 and the plurality of insulators 12 alternately in the Z direction. The stacked film 2 may be directly formed on the substrate 1 or may be formed on the substrate 1 via another layer. Each electrode layer 11 functions as a word line, for example. In each electrode layer 11, the barrier metal layer 11a is formed on side, upper, and lower faces of the electrode material layer 11b. The barrier metal layer 11a is, for example, a titanium nitride (TiN) film. The electrode material layer 11b is, for example, a metal layer such as a tungsten (W) layer. Respective insulators 12 are, for example, silicon oxide (SiO₂) films.

Each block insulator 3 is formed on side, upper and lower faces of one electrode layer 11, between insulators 12 neighboring each other in the Z direction. The insulator 3a is formed on the side, upper, and lower faces of the electrode layer 11, and is interposed between the electrode layer 11 and the insulator 12. Respective insulators 3a are, for example, aluminum oxide (Al₂O₃) films. The insulator 3b is formed on a side face of the insulator 3a. Respective insulators 3b are, for example, SiO₂ films. The insulator 3c is formed on a side face of the insulator 3b. Respective insulators 3c are, for example, silicon nitride (SiN) films. In this case, the insulator 3a has a permittivity ca, the insulator 3b has a permittivity _{ε}b, and the insulator 3c has a permittivity cc, in which there is a relationship of “_{ε}a>_{ε}c>_{ε}b”. In the present embodiment, the side face of each of the insulators 3a to 3c on the electrode layer 11 side has a convex shape that protrudes toward the electrode layer 11 side. The side face of the insulator 3a on the electrode layer 11 side forms a side face of the block insulator 3 on the electrode layer 11 side and in contact with the electrode layer 11.

Each charge storage layer 4 is formed on a side face of one electrode layer 11 via one block insulator 3. Each charge storage layer 4 is, for example, a semiconductor layer such as a polysilicon layer, and functions as a floating gate (FG) that stores charges. Each charge storage layer 4 may contain impurity atoms such as n-type impurity atoms, p-type impurity atoms, particle-size control atoms, and metal atoms. The n-type impurity atoms are, for example, phosphorus (P) atoms or arsenic (As) atoms. The p-type impurity atoms are, for example, boron (B) atoms. The particle-size control atoms are, for example, carbon (C) atoms or nitrogen (N) atoms. The metal atoms are, for example, titanium (Ti) atoms, nickel (Ni) atoms, ruthenium (Ru) atoms, cobalt (Co) atoms, tungsten (W) atoms, or molybdenum (Mo) atoms.

Each charge storage layer 4 includes one central portion having a thickness T1 and having a surface S1 in contact with the block insulator 3 on the electrode layer 11 side, and two end portions having a thickness T2 and a surface S2 in contact with the insulator 9 on the electrode layer 11 side. One of these end portions is an upper end portion, and the other of these end portions is a lower end portion. The central portion is an example of a first portion, and the end portion is an example of a second portion. The thickness T1 is an example of a first thickness, and the thickness T2 is an example of a second thickness that is less than the first thickness. The surface S1 is an example of a first face, and the surface S2 is an example of a second face that is different from the first face. In FIG. 1, the thickness T1 is the width of the central portion in the X direction, and the thickness T2 is the width of the end portion in the X direction.

In FIG. 1, each of a side face (outer circumferential surface: surface S1) of the central portion on the electrode layer 11 side and a side face (inner circumferential surface) of the central portion on the channel semiconductor layer 6 side has a flat cross-sectional shape. Accordingly, the thickness T1 is constant in the Z direction. The thickness T1 is, for example, equal to or less than 5 nm. In FIG. 1, the length of the central portion in the Z direction is the same as the length of a corresponding block insulator 3 in the Z direction.

On the other hand, in FIG. 1, a side face (inner circumferential surface) of each end portion on the channel semiconductor layer 6 side has a flat cross-sectional shape, and a side face (outer circumferential surface: surface S2) of each end portion on the electrode layer 11 side has a tapered shape. In other words, a contact area between a charge storage layer 4 and a block insulator 3 is smaller than a contact area between the charge storage layer 4 and the tunnel insulator 5. Accordingly, the thickness T2 changes in the Z direction. The maximum value of the thickness T2 is the thickness T1, and the minimum value of the thickness T2 is zero. Accordingly, the maximum value of the thickness T2 is, for example, equal to or less than 5 nm. Length L of each end portion in the Z direction is, for example, equal to or greater than 1 nm.

The thickness of each insulator 12 in the present embodiment is more than twice the length L. As a result, the end portion of each charge storage layer 4 is not in contact with the end portion of another charge storage layer 4. Accordingly, each charge storage layer 4 is formed on the side face of one electrode layer 11, and is separated for each electrode layer 11 as illustrated in FIG. 1.

The tunnel insulator 5 is formed on side faces of the plurality of charge storage layers 4. The tunnel insulator 5 is, for example, a SiO₂ film.

The channel semiconductor layer 6 is formed on the side faces of the plurality of charge storage layers 4 via the tunnel insulator 5. The channel semiconductor layer 6 is, for example, a polysilicon layer.

The core insulator 7 is formed on a side face of the channel semiconductor layer 6. The core insulator 7 is, for example, a SiO₂ film.

Each insulator 8 is formed on a side face of one insulator 12. Respective insulators 8 are, for example, SiO₂ films.

Each insulator 9 is formed on a side face of one insulator 8. As illustrated in FIG. 1, each insulator 9 of the present embodiment is in contact with surfaces S2 of two charge storage layers 4 and an outer circumferential surface of the tunnel insulator 5. Respective insulators 9 are, for example, SiO₂ films.

The core insulator 7 of the present embodiment has a columnar shape extending in the Z direction and has a circular shape in plan view. In addition, each of the channel semiconductor layer 6, the tunnel insulator 5, the charge storage layer 4, the insulator 3c, and the insulator 3b of the present embodiment has a tubular shape extending in the Z direction and has a ring-like shape in plan view. Accordingly, the channel semiconductor layer 6 of the present embodiment is surrounded by the tunnel insulator 5, the charge storage layer 4, the insulator 3c, and the insulator 3b in a ring.

Subsequently, the block insulator 3 and the charge storage layer 4 of the present embodiment will be described in more detail with reference to FIG. 1.

FIG. 1 illustrates the plurality of charge storage layers 4 separated from each other in the Z direction. As described below, when forming these charge storage layers 4, one charge storage layer 4 (polysilicon layer) is formed, and subsequently this charge storage layer 4 is partly oxidized. As a result, the plurality of insulators 9 (SiO₂ films) is formed in this charge storage layer 4 and accordingly this charge storage layer 4 is divided into multiple charge storage layers 4. The surface S2 having the tapered shape is formed by this oxidation.

FIG. 1 illustrates the block insulator 3 and the charge storage layer 4 formed for each electrode layer 11. In general, when the block insulator 3 and the charge storage layer 4 are formed for each electrode layer 11, the cross-sectional shape of the outer circumferential surface of the block insulator 3 and the cross-sectional shape of the outer circumferential surface of the charge storage layer 4 are convex. As a result, the volume of the charge storage layer 4 becomes smaller, and the performance of the charge storage layer 4 may be degraded. However, each charge storage layer 4 of the present embodiment is formed by dividing one charge storage layer 4 into multiple charge storage layers 4. Therefore, the cross-sectional shape of the outer circumferential surface (surface S1) of each charge storage layer 4 becomes flat. Therefore, according to the present embodiment, it is possible to suppress the volume of each charge storage layer 4 from being reduced due to the convex shape, and it is possible to optimize the performance of each charge storage layer 4. Further, according to the present embodiment, each charge storage layer 4 includes not only the central portion but also the end portions, and therefore it is possible to increase the volume of each charge storage layer 4. Further, according to the present embodiment, separating each charge storage layer 4 for each electrode layer 11 makes it possible to suppress signal charges from leaking between memory cells.

In the present embodiment, the cross-sectional shape of the outer circumferential surface (surface S1) of each charge storage layer 4 is flat, but the cross-sectional shape of the outer circumferential surface of each of the insulators 3a to 3c is convex. According to the present embodiment, forming the outer circumferential surface of the insulator 3c (SiN film) into a convex shape makes it possible to increase the surface area of the insulator 3c and easily apply the tunnel electric field to the tunnel insulator 5. This makes it possible to improve write characteristics and erasing characteristics of each memory cell. The insulator 3c may be an insulator having a permittivity that is higher than the permittivity of the SiN film.

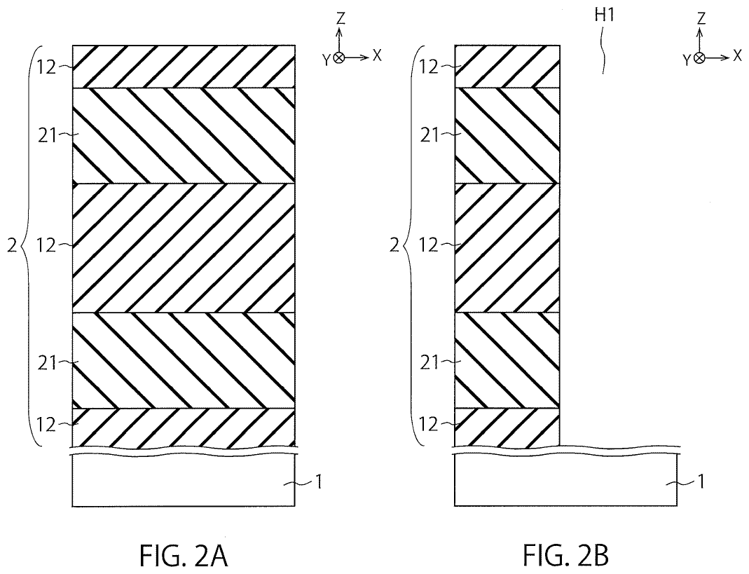

FIGS. 2A to 6B are cross-sectional diagrams illustrating a method of manufacturing the semiconductor storage device of the first embodiment.

First, the stacked film 2 is formed on the substrate 1 (FIG. 2A). The stacked film 2 is formed by alternately stacking multiple sacrificial layers 21 and multiple insulators 12 on the substrate 1. Respective sacrificial layers 21 are, for example, SiN films. The sacrificial layers 21 are examples of a lower sacrificial layer and an upper sacrificial layer.

Next, a plurality of memory holes H1 is formed in the stacked film 2 by lithography and Reactive Ion Etching (RIE) (FIG. 2B). FIG. 2B illustrates one example of these memory holes H1. Each memory hole H1 of the present embodiment has a circular shape in plan view and penetrates the stacked film 2.

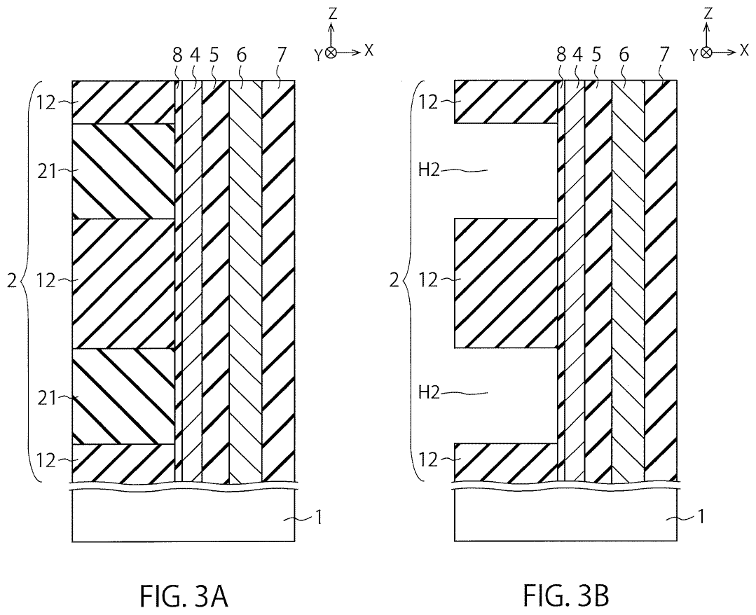

Next, the insulator 8, the charge storage layer 4, the tunnel insulator 5, the channel semiconductor layer 6, and the core insulator 7 are sequentially formed on the side face of the stacked film 2 in each memory hole H1 (FIG. 3A). In FIG. 3A, one charge storage layer 4 is continuously formed on side faces of the plurality of sacrificial layers 21 and the plurality of insulators 12.

Next, slits (not illustrated) are formed in the stacked film 2, and the sacrificial layers 21 are removed by wet etching from the slits (FIG. 3B). As a result, a plurality of concave portions H2 is formed in the stacked film 2. At this time, the insulator 8 (e.g., SiO₂ film) functions as a stopper of the wet etching. The wet etching is performed using, for example, a phosphoric acid aqueous solution.

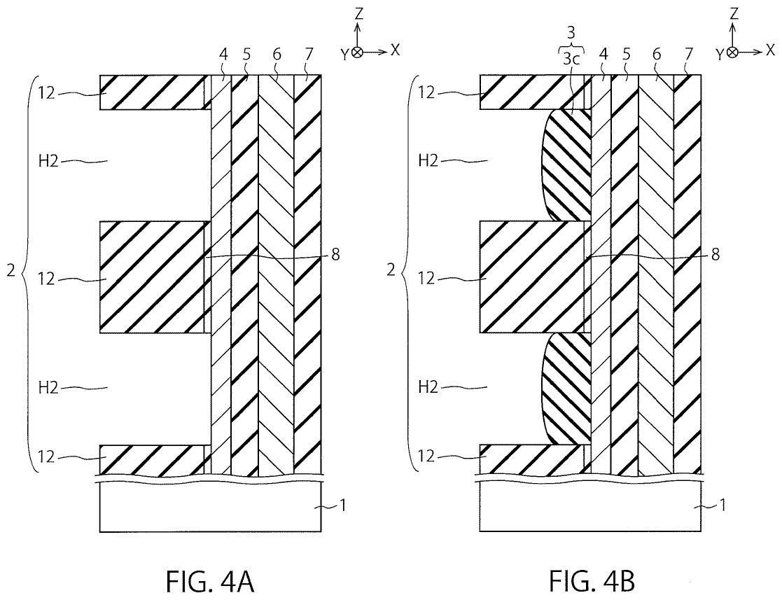

Next, the insulator 8 exposed in the concave portions H2 is removed (FIG. 4A). As a result, the insulator 8 is divided into multiple insulators 8 by being removed from the concave portions H2 while remaining on the side face of the insulator 12. Further, the side face of the charge storage layer 4 is exposed in each concave portion H2. The insulator 8 is removed by wet etching using, for example, a hydrofluoric acid aqueous solution.

Next, the insulator 3c is formed on the side face of the charge storage layer 4 in each concave portion H2 (FIG. 4B). The insulator 3c of the present embodiment is formed by selective growth from the side face of the charge storage layer 4 in each concave portion H2. As a result, the insulator 3c of the present embodiment is selectively formed on the side face of the charge storage layer 4, among the side face of the charge storage layer 4, the upper faces of the insulators 12 and 8, and the lower faces of the insulators 12 and 8, in each concave portion H2. Further, the cross-sectional shape of the side face of the insulator 3c on the concave portion H2 side becomes convex.

This selective growth can be realized, for example, by using polysilicon layers as the charge storage layers 4 and SiN films as the insulators 3c. In this case, the insulators 3c may not be the SiN films but other insulators capable of selective growth. Further details of this selective growth will be described below.

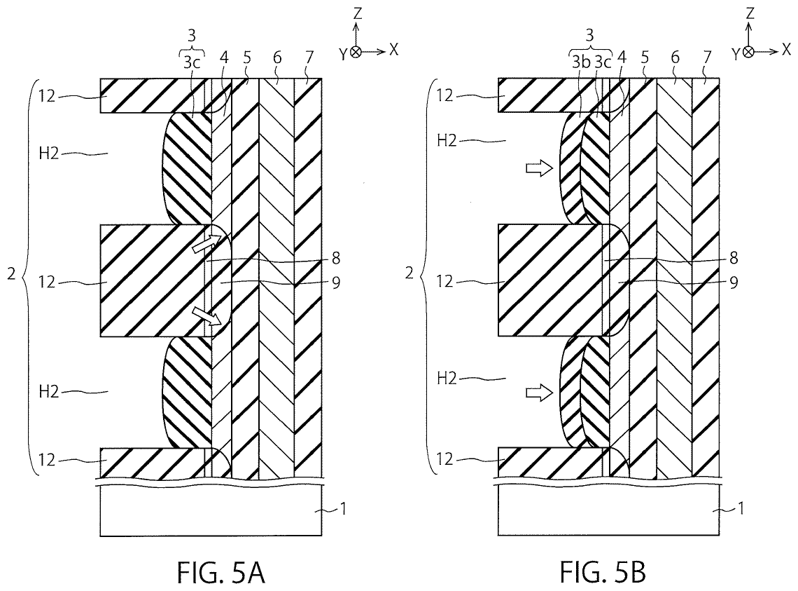

Next, water (H₂O) is used to partly oxidize the charge storage layer 4 (FIG. 5A). As a result, the charge storage layer 4 (e.g., polysilicon layer) on the side of the insulator 12 is oxidized, and the plurality of insulators 9 (e.g., SiO₂ films) is formed in the charge storage layer 4. As a result, one charge storage layer 4 is divided into multiple charge storage layers 4. Each charge storage layer 4 is formed by this oxidation so as to have the surface S1 having a flat shape and the surface S2 having a tapered shape (refer to FIG. 1). This oxidation may be performed by radical oxidation.

Next, the insulator 3c is partly oxidized (FIG. 5B). As a result, the insulator 3b (e.g., SiO₂ film) is formed in the insulator 3c (e.g., SiN film). Since this oxidation progresses from the side face of the insulator 3c on the concave portion H2 side, the insulator 3b is formed on the side face of the insulator 3c on the concave portion H2 side, as illustrated in FIG. 5B. As a result, the shape of the side face of each of the insulators 3b and 3c on the concave portion H2 side becomes convex.

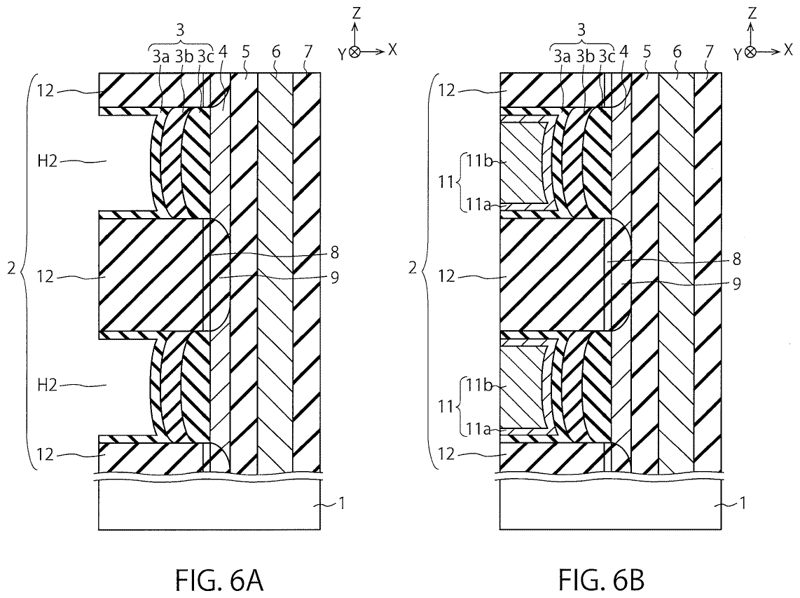

Next, the insulator 3a is formed in each concave portion H2 (FIG. 6A). As a result, the insulator 3a is formed on the side face of the insulator 3b, the upper face of the insulator 12, and the lower face of the insulator 12 in each concave portion H2. In this manner, the block insulator 3 is formed in each concave portion H2. The insulator 3a of the present embodiment is formed conformally and therefore formed so as to have a convex-shaped side face on the concave portion H2 side.

Next, the barrier metal layer 11a and the electrode material layer 11b are sequentially formed in each concave portion H2 (FIG. 6B). As a result, an electrode layer 11 is formed in each concave portion H2 via a block insulator 3, and the stacked film 2 including the plurality of electrode layers 11 and the plurality of insulators 12 is formed on the substrate 1.

Subsequently, various plugs, interconnect layers, inter layer dielectrics and the like are formed on the substrate 1. In this manner, the semiconductor storage device of the present embodiment is manufactured.

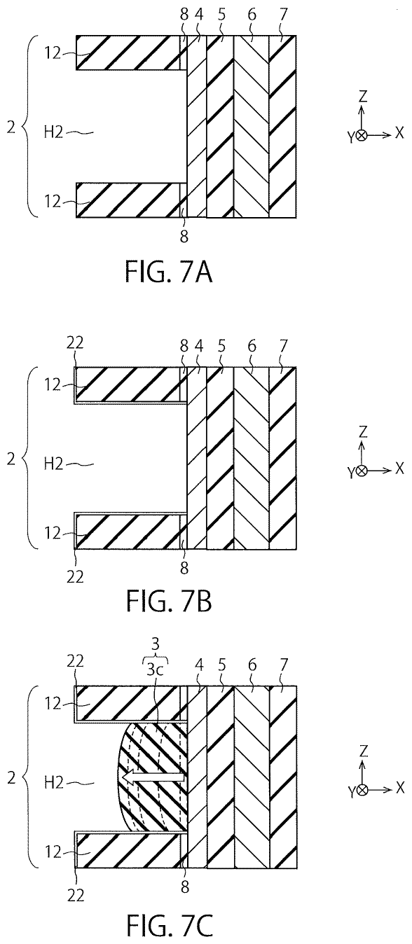

FIGS. 7A to 7C are cross-sectional diagrams illustrating details of the method of manufacturing the semiconductor storage device of the first embodiment.

FIG. 7A illustrates a part of FIG. 4A. In the present embodiment, before the insulator 3c (e.g., SiN film) is formed on the side face of the charge storage layer 4 (e.g., polysilicon layer) in each concave portion H2, an inhibitor may be adhered to the surfaces of the insulators 12 and 8 (e.g., SiO₂ films) (FIG. 7B). As a result, an inhibitor area 22 is formed on the surfaces of the insulators 12 and 8. The inhibitor area 22 is an area containing the inhibitor. The inhibitor is a substance that suppresses the Si precursor from adhering to the surfaces of the insulators 12 and 8. In FIG. 7B, the inhibitor area 22 is formed on the upper faces of the insulators 12 and 8 and the lower faces of the insulators 12 and 8 in the concave portion H2 as well as on the side faces of the insulators 12 outside the concave portion H2.

Next, the Si precursor is used to form the insulator 3c on the side face of the charge storage layer 4 in each concave portion H2 (FIG. 7C). In FIG. 7C, the inhibitor area 22 is formed on the surfaces of the insulators 12 and 8. Therefore, the Si precursor adheres to the side face of the charge storage layer 4, but is less likely to adhere to the surfaces of the insulators 12 and 8. Therefore, according to the present embodiment, the insulator 3c can be selectively formed on the side face of the charge storage layer 4, among the side face of the charge storage layer 4, the upper faces of the insulators 12 and 8, and the lower faces of the insulators 12 and 8, in each concave portion H2.

The insulator 3c of the present embodiment selectively grows from the side face of the charge storage layer 4 in each concave portion H2, and therefore the shape of the side face of the insulator 3c becomes convex. Further, if the wet etching in the process of FIG. 4A is insufficient, each insulator 8 in FIG. 7A to FIG. 7C may protrude inside the concave portion H2 with respect to the surface of the insulator 12. If the surface of this protrusion has a tapered shape, the inhibitor is less likely to adhere to this surface. Accordingly, such an insulator 8 may also promote the shape of the side face of the insulator 3c to become convex.

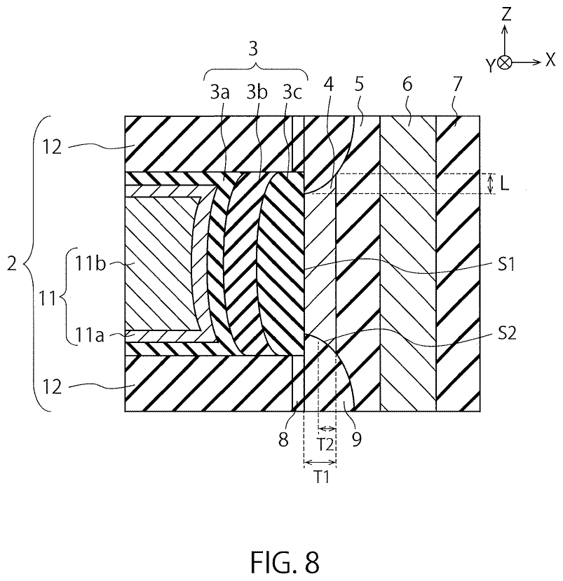

FIG. 8 is a cross-sectional diagram illustrating the structure of a semiconductor storage device of a modified embodiment of the first embodiment.

A charge storage layer 4 of the present modified embodiment includes one central portion having the thickness T1 and having the surface S1 in contact with the block insulator 3 on the electrode layer 11 side, and two end portions having the thickness T2 and having the surface S2 in contact with the insulator 9 on the electrode layer 11 side. However, the length of the central portion of the present modified embodiment in the Z direction, that is, the length of the surface S1 in the Z direction, is shorter than the length of the block insulator 3 in the Z direction. Such a structure can be realized, for example, by increasing the oxidation time in the process of FIG. 5A. According to the present modified embodiment, setting the shape of the charge storage layer 4 in this way makes it possible to downsize each memory cell, for example.

As described above, each block insulator 3 of the present embodiment has a convex-shaped side face on the electrode layer 11 side. Further, each charge storage layer 4 of the present embodiment includes the central portion having the thickness T1 and having the surface S1 in contact with the block insulator 3 and the end portion having the thickness T2 that is less than the thickness T1 and having the surface S2 that is different from the surface S1. Therefore, according to the present embodiment, it is possible to form the charge storage layer 4 having suitable performances, as described above.

### Second Embodiment

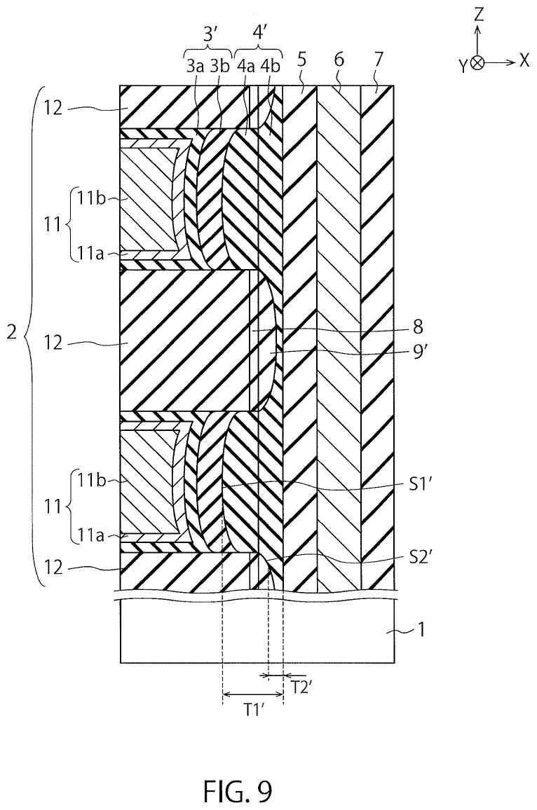

FIG. 9 is a cross-sectional diagram illustrating the structure of a semiconductor storage device of a second embodiment.

The semiconductor storage device (FIG. 9) of the present embodiment is similar, in structure, to the semiconductor storage device (FIG. 1) of the first embodiment. However, the semiconductor storage device of the present embodiment includes a plurality of block insulators 3′, a charge storage layer 4′, and a plurality of insulators 9′, instead of the plurality of block insulators 3, the plurality of charge storage layers 4, and the plurality of insulators 9 described above. Similarly to the block insulator 3, the block insulator 3′ is examples of the first, second and fifth insulators.

Each block insulator 3′ includes an insulator 3a and an insulator 3b, but includes no insulator 3c. The shapes and materials of the insulators 3a and 3b of the present embodiment are similar to the shapes and materials of the insulators 3a and 3b of the first embodiment. Accordingly, the insulators 3a of the present embodiment are, for example, Al₂O₃ films. Further, the insulators 3b of the present embodiment are, for example, SiO₂ films.

The charge storage layer 4′ is formed continuously on side faces of the plurality of electrode layers 11 via the plurality of block insulators 3′. The charge storage layer 4′ includes a plurality of charge storage insulators 4a and a charge storage insulator 4b. Respective charge storage insulators 4a and 4b are, for example, insulators such as SiN films, and function as charge trapping (CT) films that trap and store charges. Respective charge storage insulators 4a and 4b may include some impurity atoms.

The shapes and materials of respective charge storage insulators 4a of the present embodiment are similar to the shapes and materials of the insulators 3c of the first embodiment. Accordingly, each charge storage insulator 4a is formed on a side face of the insulator 4b. A side face of each charge storage insulator 4a on the electrode layer 11 side has a convex shape that protrudes toward the electrode layer 11 side.

On the other hand, the shape of the charge storage insulator 4b of the present embodiment is similar to the shape of the plurality of charge storage layers 4 of the first embodiment. However, the charge storage insulator 4b is not separated for each electrode layer 11. As illustrated in FIG. 9, the charge storage insulator 4b is formed continuously on side faces of the plurality of charge storage insulators 4a.

The charge storage layer 4′ includes a plurality of central portions having a thickness T1′ and having a surface S1′ that is in contact with the block insulator 3′ on the electrode layer 11 side and a plurality of end portions having a thickness T2′ and having a surface S2′ that is in contact with the insulator 9′ on the electrode layer 11 side. The central portion is an example of the first portion, and the end portion is an example of the second portion. The thickness T1′ is an example of the first thickness. The thickness T2′ is an example of the second thickness that is less than the first thickness. The surface S1′ is an example of the first face. The surface S2′ is an example of the second face that is different from the first face.

Each central portion in FIG. 9 includes a charge storage insulator 4a and a charge storage insulator 4b. In FIG. 9, a side face (inner circumferential surface) of each central portion on a channel semiconductor layer 6 side has a flat cross-sectional shape, but a side face (outer circumferential surface: surface S1′) of each central portion on the electrode layer 11 side has a convex shape. Accordingly, the thickness T1′ changes in the Z direction. In FIG. 9, the length of each central portion in the Z direction is equal to the length of a corresponding block insulator 3 in the Z direction. Like the example in FIG. 8, the length of each central portion in the Z direction may be shorter than the length of a corresponding block insulator 3 in the Z direction.

On the other hand, each end portion in FIG. 9 is made of the charge storage insulator 4b. In FIG. 9, the side face (inner circumferential surface) of the channel semiconductor layer 6 of each end portion has a flat cross-sectional shape, but the side face (outer circumferential surface: surface S2′) of each end portion on the electrode layer 11 side has a tapered shape, in more detail, a concave shape. Accordingly, the thickness T2′ changes in the Z direction. In FIG. 9, the maximum value of the thickness T2′ is the thickness T2′ at upper and lower ends of each end portion. The minimum value of the thickness T2′ is the thickness T2′ at a halfway point between the upper and lower ends of each end portion. The maximum value of the thickness T2′ is, for example, equal to or less than nm. The difference between the maximum and minimum values of the thickness T2′ is, for example, equal to or greater than 1 nm. The maximum value of the thickness T2′ in the present embodiment corresponds to the maximum value of the thickness of the charge storage insulator 4b.

Each insulator 9′ is formed on a side face of one insulator 8. Each insulator 9′ of the present embodiment is in contact with the surface S2′ of one end portion of the charge storage layer 4′, as illustrated in FIG. 9. Respective insulators 9′ are, for example, SiO₂ films.

A core insulator 7 of the present embodiment has a columnar shape that extends in the Z direction and has a circular shape in plan view. Further, each of the channel semiconductor layer 6, the tunnel insulator 5, the charge storage insulator 4b, the charge storage insulator 4a, and the insulator 3b of the present embodiment has a tubular shape that extends in the Z direction and has a ring-like shape in plan view. Accordingly, the channel semiconductor layer 6 of the present embodiment is surrounded by the tunnel insulator 5, the charge storage insulator 4b, the charge storage insulator 4a, and the insulator 3b in a ring.

Subsequently, the block insulator 3′ and the charge storage layer 4′ of the present embodiment will be described in more detail with reference to FIG. 9.

FIG. 9 illustrates the plurality of charge storage insulators 4a and one charge storage insulator 4b formed on the side face of the charge storage insulator 4a. As described below, the charge storage insulator 4a is formed similarly to the insulator 3c of the first embodiment, and the charge storage insulator 4b is formed similarly to the charge storage layer 4 of the first embodiment. Accordingly, when forming the end portion of the charge storage insulator 4b, the charge storage insulator 4b is partly oxidized. As a result, the plurality of insulators 9 (SiO₂ films) is formed in the charge storage insulator 4b (SiN film), and accordingly the end portion of the charge storage insulator 4b is formed. At this time, the charge storage insulator 4b is different from the charge storage layer 4 of the first embodiment, and may be oxidized so as not to be divided into multiple charge storage insulators 4b. The surface S2 having the tapered shape is formed by this oxidation.

FIG. 9 illustrates the block insulator 3′ and the charge storage insulator 4a formed for each electrode layer 11. In general, when the block insulator 3′ and the charge storage insulator 4a are formed for each electrode layer 11, the cross-sectional shape of the outer circumferential surface of the block insulator 3′ and the cross-sectional shape of the outer circumferential surface of the charge storage insulator 4a are convex, as illustrated in FIG. 9. As a result, the volume of the charge storage layer 4′ becomes smaller, and the performance of the charge storage layer 4′ may be degraded. However, the charge storage layer 4′ of the present embodiment is formed using not only the charge storage insulator 4a but also the charge storage insulator 4b, and accordingly has a large volume. Therefore, according to the present embodiment, it is possible to prevent the volume of the charge storage layer 4′ from being reduced due to the convex shape, and it is possible to optimize the performance of the charge storage layer 4′.

Further, according to the present embodiment, the charge storage layer 4′ incudes not only the central portion but also the end portion, and therefore it is possible to increase the volume of the charge storage layer 4′. In addition, not dividing the charge storage insulator 4b into multiple charge storage insulators 4b contributes to increasing the volume of the charge storage layer 4′.

In the present embodiment, the charge storage insulator 4b is not divided into multiple charge storage insulators 4b, but the thickness T2′ at the end portion of the charge storage layer 4′ is small. This makes it possible to suppress signal charges from leaking between memory cells. From this point of view, it is desirable to set a large difference between maximum and minimum values of the thickness T2′. The difference between the maximum and minimum values of the thickness T2′ is, for example, equal to or greater than 1 nm.

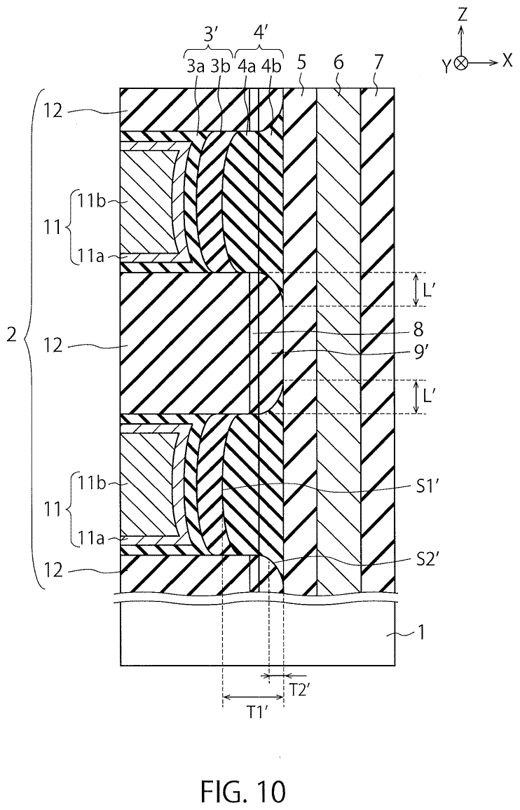

FIG. 10 is a cross-sectional diagram illustrating the structure of a semiconductor storage device of a first modified embodiment of the second embodiment.

The semiconductor storage device of the present modified embodiment in FIG. 10 is similar, in structure, to the semiconductor storage device in FIG. 9. However, the semiconductor storage device of the present modified embodiment includes a plurality of charge storage insulators 4b separated for each electrode layer 11, and as a result, includes a plurality of charge storage layers 4′ separated for each electrode layer 11.

As illustrated in FIG. 10, each charge storage layer 4′ of the present modified embodiment includes one central portion having the thickness T1′ and having the surface S1′ that is in contact with the block insulator 3′ on the electrode layer 11 side, and two end portions having the thickness T2′ and having the surface S2′ that is in contact with the insulator 9′ on the electrode layer 11 side. Length L′ of each end portion in the Z direction is, for example, equal to or greater than 1 nm. Each charge storage insulator 4b of the present modified embodiment can be formed in the same manner as each charge storage layer 4 of the first embodiment.

According to the present modified embodiment, separating each charge storage layer 4′ for each electrode layer 11 makes it possible to suppress signal charges from leaking between memory cells.

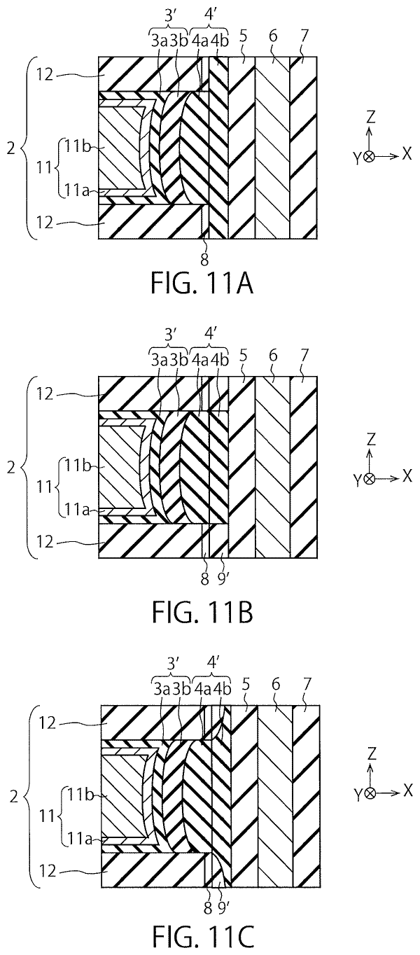

FIGS. 11A to 11C are cross-sectional diagrams for explaining advantages of the semiconductor storage device of the second embodiment.

FIG. 11A illustrates a semiconductor storage device of a first comparative example of the present embodiment. The semiconductor storage device of the present comparative example includes charge storage insulators 4b not separated for each electrode layer 11. The thickness of the charge storage insulator 4b of the present comparative example is constant. The semiconductor storage device of the present comparative example is advantageous in that memory cells have good write characteristics because the volume of the charge storage layer 4′ is large. However, the charge storage insulator 4b of the present comparative example is not separated for each electrode layer 11 and accordingly charge retention characteristics of memory cells may be insufficient.

FIG. 11B illustrates a semiconductor storage device of a second comparative example of the present embodiment. The semiconductor storage device of the present comparative example includes a plurality of charge storage insulators 4b separated for each electrode layer 11, and accordingly includes a plurality of charge storage layers 4′ separated for each electrode layer 11. However, each charge storage layer 4′ of the present comparative example includes the above-described central portion but does not include the above-described end portion. The semiconductor storage device of the present comparative example is advantageous in that the memory cell has good charge retention characteristics since the charge storage insulator 4b is separated for each electrode layer 11. However, since the volume of the charge storage layer 4′ of the present comparative example is small, the memory cell may have insufficient write characteristics.

Like FIG. 9, FIG. 11C illustrates the semiconductor storage device of the present embodiment. The semiconductor storage device of the present embodiment includes the charge storage insulator 4b not separated for each electrode layer 11. However, each charge storage layer 4′ of the present embodiment includes the central portion and the end portion described above. Therefore, according to the present embodiment, increasing the volume of the charge storage layer 4′ at the end portion makes it possible to improve write characteristics of each memory cell. Further, according to the present embodiment, reducing the thickness T2′ of the end portion makes it possible to improve charge retention characteristics of each memory cell.

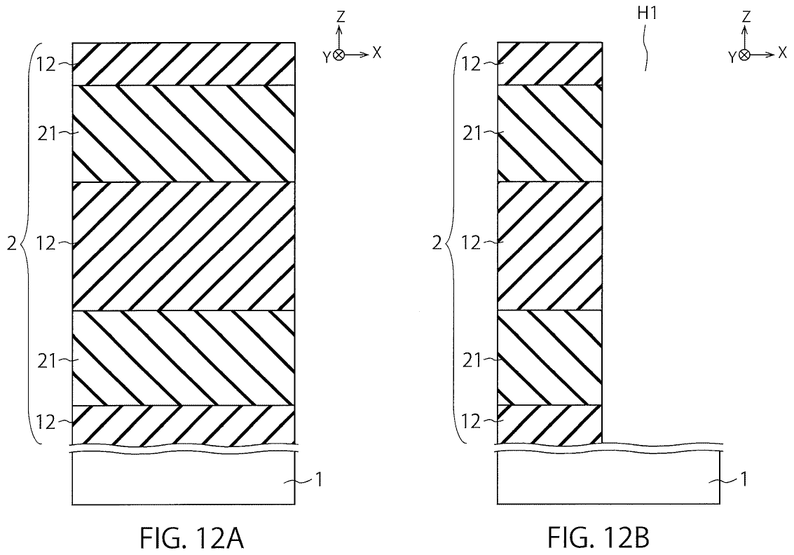

FIGS. 12A to 15B are cross-sectional diagrams illustrating a method of manufacturing the semiconductor storage device of the second embodiment. In the following description, matters common to those of the first embodiment will not be described and will be omitted appropriately.

First, the stacked film 2 is formed on the substrate 1 (FIG. 12A). The stacked film 2 is formed by alternately stacking the plurality of sacrificial layers 21 and the plurality of insulators 12 on the substrate 1.

Next, the plurality of memory holes H1 is formed in the stacked film 2 (FIG. 12B). FIG. 12B illustrates one of these memory holes H1.

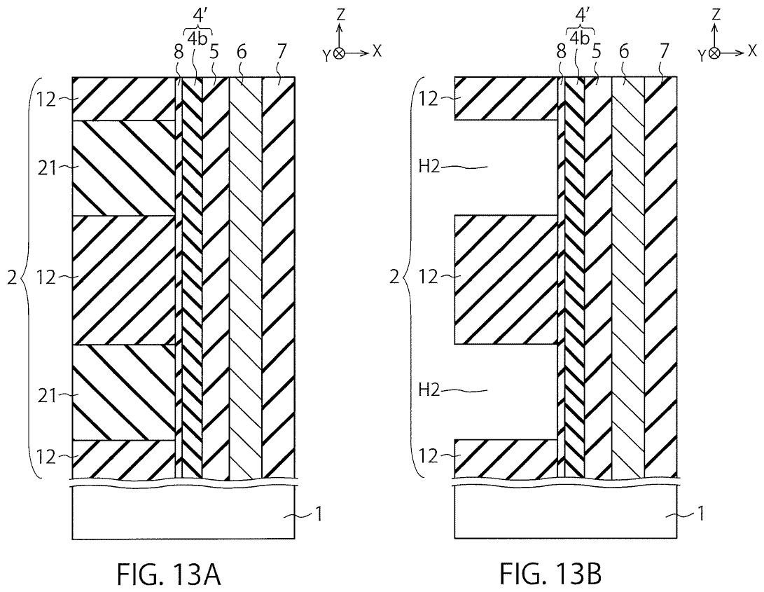

Next, the insulator 8, the charge storage insulator 4b, the tunnel insulator 5, the channel semiconductor layer 6, and the core insulator 7 are sequentially formed on the side face of the stacked film 2 in each memory hole H1 (FIG. 13A).

Next, slits (not illustrated) are formed in the stacked film 2, and the sacrificial layers 21 are removed by wet etching from the slits (FIG. 13B). As a result, a plurality of concave portions H2 is formed in the stacked film 2. At this time, the insulator 8 (e.g., SiO₂ film) functions as a stopper of the wet etching. The wet etching is performed using, for example, a phosphoric acid aqueous solution.

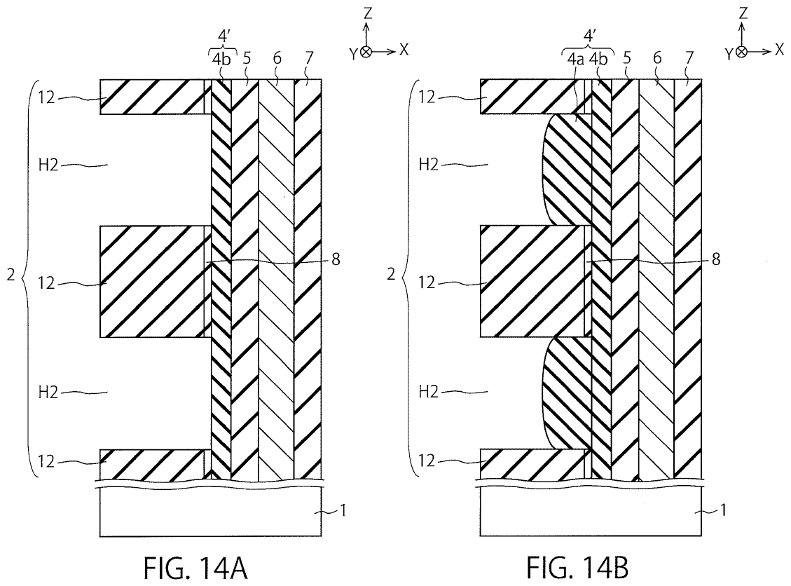

Next, the insulator 8 exposed in the concave portion H2 is removed (FIG. 14A). As a result, the insulator 8 is divided into multiple insulators 8 by being removed from the concave portion H2 while remaining on the side face of the insulator 12. Further, the side face of the charge storage insulator 4b is exposed in each concave portion H2. The insulator 8 is removed by wet etching using, for example, a hydrofluoric acid aqueous solution.

Next, the charge storage insulator 4a is formed on the side face of the charge storage insulator 4b in each concave portion H2 (FIG. 14B). The charge storage insulator 4a of the present embodiment is formed by selective growth from the side face of the charge storage insulator 4b in each concave portion H2. As a result, the charge storage insulator 4a of the present embodiment is selectively formed on the side face of the charge storage insulator 4b, among the side face of the charge storage insulator 4b, the upper faces of the insulators 12 and 8, and the lower faces of the insulators 12 and 8, in each concave portion H2. Further, the cross-sectional shape of the side face of the charge storage insulator 4a on the concave portion H2 side becomes convex.

The selective growth of the present embodiment can be realized, for example, by using SiN films as the charge storage insulators 4b and SiN films as the charge storage insulators 4a. The selective growth of the present embodiment may be performed using an inhibitor, like the selective growth of the first embodiment (refer to FIGS. 7A to 7C).

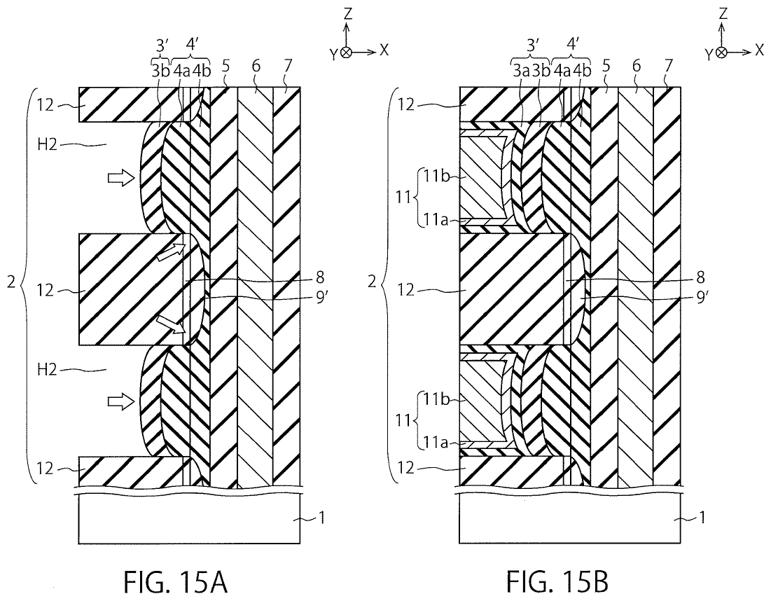

Next, H₂O is used to partly oxidize the charge storage insulators 4a and 4b (FIG. 15A). As a result, the charge storage insulator 4b (e.g., SiN film) on the side of the insulator 12 is oxidized, and the plurality of insulators 9 (e.g., SiO₂ films) is formed in the charge storage insulator 4b. At this time, the charge storage insulator 4b is different from the charge storage layer 4 of the first embodiment, and is oxidized so as not to be divided into multiple charge storage insulators 4b. Such an oxidation can be realized, for example, by reducing the oxidation time. On the other hand, when manufacturing the semiconductor storage device in FIG. 10, the charge storage insulator 4b is oxidized, like the charge storage layer 4 of the first embodiment, so as to be divided into multiple charge storage insulators 4b.

In oxidation, the insulator 3b (e.g., SiO₂ film) is further formed in the charge storage insulator 4a (e.g., SiN film). Since this oxidation progresses from the side face of the charge storage insulator 4a on the concave portion H2 side, the insulator 3b is formed on the side face of the charge storage insulator 4a on the concave portion H2 side, as illustrated in FIG. 15A. As a result, the shape of the side face of the charge storage insulator 4a on the concave portion H2 side and the shape of the side face of the insulator 3b on the concave portion H2 side become convex. The charge storage layer 4′ is formed by this oxidation so as to have the surface S1 having a convex shape and the surface S2 having a tapered shape (concave shape) (refer to FIG. 9). This oxidation may be performed by radical oxidation.

This oxidation may be performed using an oxidizing agent other than H₂O. Examples of such an oxidizing agent include oxygen (02), deuterium oxide (D₂O), OH radical, and OD radical. However, H represents hydrogen and D represents deuterium. The state of the oxidizing agent may be any of molecule, atom, and radical.

Next, the insulator 3a is formed in each concave portion H2 (FIG. 15B). As a result, the insulator 3a is formed on the side face of the insulator 3b, the upper face of the insulator 12, and the lower face of the insulator 12, in each concave portion H2. In this manner, the block insulator 3′ is formed in each concave portion H2. The insulator 3a of the present embodiment is formed conformally and therefore formed so as to have a convex-shaped side face on the concave portion H2 side.

Next, the barrier metal layer 11a and the electrode material layer 11b are sequentially formed in each concave portion H2 (FIG. 15B). As a result, an electrode layers 11 is formed in each concave portion H2 via a block insulator 3′, and the stacked film 2 including the plurality of electrode layers 11 and the plurality of insulators 12 is formed on the substrate 1.

Subsequently, various plugs, interconnect layers, inter layer dielectrics and the like are formed on the substrate 1. In this manner, the semiconductor storage device of the present embodiment is manufactured.

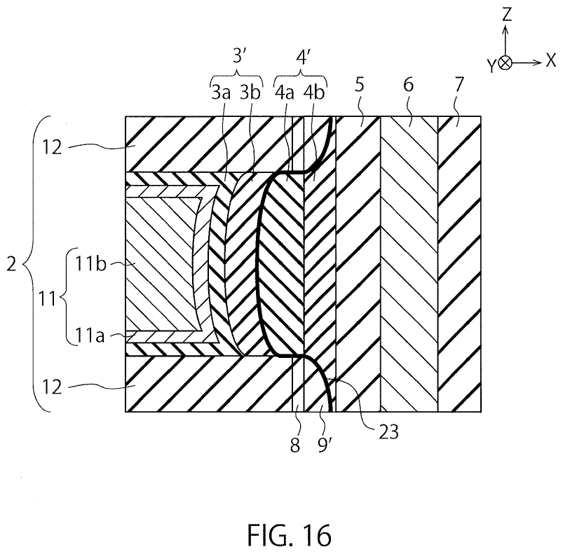

FIG. 16 is a cross-sectional diagram illustrating the structure of a semiconductor storage device of a second modified embodiment of the second embodiment.

The semiconductor storage device of the present modified embodiment in FIG. 16 is similar, in structure, to the semiconductor storage device in FIG. 9 (or FIG. 10). However, in the present modified embodiment, the nitrogen concentration of a surface 23 of the charge storage layer 4′ on the electrode layer 11 side is higher than the nitrogen concentration inside the charge storage layer 4′. The surface 23 includes the surface S1 and the surface S2 described above. For example, the nitrogen concentration of the surface 23 of the charge storage layer 4′ may be higher than twice the nitrogen concentration inside the charge storage layer 4′.

When the charge storage insulators 4a and 4b are partly oxidized in the process of FIG. 15A, a portion of the charge storage insulator 4a changes into the insulator 3b and a portion of the charge storage insulator 4b changes into the insulator 9′. At this time, atoms existing in the areas of the insulators 3b and 9′ before oxidation may diffuse to the surface 23 of the charge storage layer 4′. As a result, as illustrated in FIG. 16, the nitrogen concentration of the surface 23 of the charge storage layer 4′ becomes higher than the nitrogen concentration inside the charge storage layer 4′. The surface 23 containing nitrogen at a higher concentration can suppress signal charges inside the charge storage layer 4′ from leaking through the surface 23, for example.

As described above, each block insulator 3′ of the present embodiment has a convex-shaped side face on the electrode layer 11 side. Further, the charge storage layer 4′ of the present embodiment includes the central portion having the thickness T1′ and having the surface S1′ in contact with the block insulator 3′, and the end portion having the thickness T2′ that is less than the thickness T1′ and having the surface S2′ that is different from the surface S1′. Therefore, according to the present embodiment, as described above, it is possible to form the charge storage layer 4′ having suitable performances.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A semiconductor storage device comprising:
a lower electrode layer;
a lower insulator provided on a side of a first direction of the lower electrode layer;
an upper electrode layer provided on a side of the first direction of the lower insulator;
an upper insulator provided on a side of the first direction of the upper electrode layer;
a first insulator provided on a side of a second direction of the upper electrode layer, the second direction intersecting with the first direction;
a second insulator provided between the lower insulator and the upper electrode layer, between the upper electrode layer and the upper insulator, and between the upper electrode layer and the first insulator;
a charge storage layer provided on a side of the second direction of the first insulator;
a third insulator provided on a side of the second direction of the charge storage layer; and
a semiconductor layer provided on a side of the second direction of the third insulator,
wherein
a side face of the first insulator on a side of the upper electrode layer has a convex shape protruding toward the upper electrode layer,
the charge storage layer includes a first portion having a first thickness in the second direction, and a second portion having a second thickness in the second direction, the second thickness being less than the first thickness, and
the first portion is in contact with the first insulator.

2. The device of claim 1, further comprising a fourth insulator between the lower insulator and the third insulator,
wherein
the lower insulator and the fourth insulator include silicon and oxygen, and
the second portion is in contact with the fourth insulator.

3. The device of claim 1, wherein a contact area between the charge storage layer and the first insulator is smaller than a contact area between the charge storage layer and the third insulator.

4. The device of claim 1, wherein the charge storage layer is a semiconductor layer.

5. The device of claim 4, wherein the charge storage layer includes phosphorus (P), arsenic (As), boron (B), carbon (C), nitrogen (N), titanium (Ti), nickel (Ni), ruthenium (Ru), cobalt (Co), tungsten (W) or molybdenum (Mo).

6. The device of claim 1, wherein a length of the lower insulator in the first direction is equal to or longer than twice a length of the second portion in the first direction.

7. The device of claim 1, wherein a maximum value of a thickness of the charge storage layer in the second direction is equal to or less than 5 nm.

8. The device of claim 1, wherein a length of the first portion in the first direction is shorter than a length of the first insulator in the first direction.

9. The device of claim 1, wherein the first insulator includes a fifth insulator having a permittivity higher than a permittivity of a silicon nitride film.

10. A semiconductor storage device comprising:
a lower electrode layer;
a lower insulator provided on a side of a first direction of the lower electrode layer;
an upper electrode layer provided on a side of the first direction of the lower insulator;
an upper insulator provided on a side of the first direction of the upper electrode layer;
a first insulator provided on a side of a second direction of the upper electrode layer, the second direction intersecting with the first direction;
a second insulator provided between the lower insulator and the upper electrode layer, between the upper electrode layer and the upper insulator, and between the upper electrode layer and the first insulator;
a charge storage layer;
a third insulator provided on a side of the second direction of the charge storage layer; and
a semiconductor layer provided on a side of the second direction of the third insulator,
wherein
a side face of the first insulator on a side of the upper electrode layer has a convex shape protruding toward the upper electrode layer,
the charge storage layer includes a first portion provided on a side of the second direction of the upper electrode layer, a second portion provided on a side of the second direction of the lower insulator, and a third portion provided on a side of the second direction of the lower electrode layer,
the first portion has a first thickness in the second direction, and the second portion has a second thickness in the second direction, the second thickness being less than the first thickness, and
the first portion is in contact with the first insulator.

11. The device of claim 10, further comprising a fourth insulator between the lower insulator and the charge storage layer,
wherein
the lower insulator and the fourth insulator include silicon and oxygen, and
the second portion is in contact with the fourth insulator.

12. The device of claim 10, wherein a side face of the first portion on a side of the upper electrode layer has a convex shape protruding toward the upper electrode layer.

13. The device of claim 10, wherein a nitrogen concentration of a side face of the first portion on a side of the upper electrode layer and a side face of the second portion on a side of the lower insulator is higher than a nitrogen concentration inside the charge storage layer.

14. The device of claim 10, wherein the first portion, the second portion and the third portion of the charge storage layer is provided continuously in the first direction.

15. The device of claim 10, wherein a maximum value of the second thickness is equal to or less than 5 nm, and a difference between the maximum value and a minimum value of the second thickness is equal to or greater than 1 nm.

16. A method of manufacturing a semiconductor storage device including a lower insulator, an electrode layer, an upper insulator, a charge storage layer, a first insulator, a second insulator, a third insulator and a semiconductor layer, the method comprising:
forming a stacked film including a lower sacrificial layer, the lower insulator provided on a side of a first direction of the lower sacrificial layer, an upper sacrificial layer provided on a side of the first direction of the lower insulator, and the upper insulator provided on a side of the first direction of the upper sacrificial layer;
forming, in the stacked film, a memory hole extending in the first direction;
forming, in the memory hole, the charge storage layer, the third insulator and the semiconductor layer in order from a side of a side face of the stacked film;
removing the upper sacrificial layer;
forming, in a portion where the upper sacrificial layer has been removed, the first insulator in contact with the charge storage layer;
oxidizing a portion of the charge storage layer and a portion of the first insulator;
forming, in the portion where the upper sacrificial layer has been removed, the second insulator in contact with the oxidized portion of the charge storage layer, the lower insulator and the upper insulator; and
forming, in the portion where the upper sacrificial layer has been removed, the electrode layer in contact with the second insulator,
wherein
the oxidized portion and a remaining portion are formed in the charge storage layer when the portion of the charge storage layer and the portion of the first insulator are oxidized, and
the remaining portion includes a first portion having a first thickness in a second direction that intersects with the first direction, and a second portion having a second thickness in the second direction, the second thickness being less than the first thickness.

17. The method of claim 16, wherein
the first insulator includes a lower portion in contact with the lower insulator, an upper portion in contact with the upper insulator, and an intermediate portion provided between the lower portion and the upper portion, and
in the second direction, a thickness of the intermediate portion is more than a thickness of the lower portion and a thickness of the upepr portion.

18. The method of claim 16, wherein the remaining portion is in contact with the third insulator.

19. The method of claim 16, wherein the first insulator selectively grows from a side face of the charge storage layer exposed to the portion where the upper sacrificial layer has been removed, when the first insulator is formed.

20. The method of claim 19, wherein the first insulator is formed after an inhibiter adheres to an upper face of the lower insulator and a lower face of the upper insulator,
wherein the upper face of the lower insulator and the lower face of the upper insulator are exposed to the portion where the upper sacrificial layer has been removed.
